(19) United States
(12) Patent Application Publication
(10) Pub. No.: US 2012/0189025 A1
(43) Pub. Date: Jul. 26, 2012

(54) MONOLITHIC LASER SOURCE USING RING-RESONATOR REFLECTORS

(75) Inventors: Xuezhe Zheng, San Diego, CA (US); Ashok V. Krishnamoorthy, San Diego, CA (US); John E. Cunningham, San Diego, CA (US)

(73) Assignee: ORACLE INTERNATIONAL CORPORATION, Redwood City, CA (US)

(21) Appl. No.: 12/952,838

(22) Filed: Nov. 23, 2010

(51) Int. Cl. H01S 5/06

(52) U.S. Cl. 372/20

(57) ABSTRACT

In a laser source, a first optical waveguide includes a gain medium, and a second optical waveguide includes a phase tuner which adjusts a phase value of the phase tuner to specify the wavelength of the laser source. Furthermore, the laser source includes a first ring resonator and a second ring resonator, which, respectively, are optically coupled to the first optical waveguide and the second optical waveguide at opposite ends of the laser source. In particular, coupling wavelengths of the first and second ring resonators may match a wavelength of the optical signal, thereby defining an optical resonance cavity in the laser source and selecting a laser mode of the laser source which is associated with the wavelength. Additionally, the laser source includes an optical amplifier that receives and amplifies the optical signal output from the optical resonance cavity.

### GOVERNMENT LICENSE RIGHTS

The United States Government has a paid-up license in this invention and the right in limited circumstances to require the patent owner to license others on reasonable terms as provided for by the terms of Agreement No. HR0011-08-9-0001 awarded by the Defense Advanced Research Projects Administration.

### BACKGROUND

1. Field

The present disclosure relates to techniques for communicating optical signals. More specifically, the present disclosure relates to a laser source that includes an optical resonance cavity defined by ring-resonator reflectors.

2. Related Art

Silicon photonics is a promising technology that can provide large communication bandwidth, low latency and low power consumption for inter-chip and intra-chip connections. In the last few years, significant progress has been made in developing low-cost components for use in inter-chip and intra-chip silicon-photonic connections, including: high-bandwidth efficient silicon modulators, low-loss optical waveguides, wavelength-division-multiplexing (WDM) components, and high-speed CMOS optical-waveguide photo-detectors. However, a suitable low-cost WDM laser source remains a challenge and poses an obstacle to implementing WDM silicon-photonic links

In particular, existing WDM lasers (such as those used to transmit optical signals in WDM telecommunications systems) are usually very expensive and are typically single-wavelength sources. Because future WDM silicon-photonic links are expected to include thousands of optical channels (or more), the total cost of these WDM laser sources is likely to be prohibitive. Furthermore, in order to reduce the tuning power of a WDM silicon-photonic link, the wavelengths output by the WDM laser source for each optical channel may need to have a very narrow line width (such as less than a few picometers), which can be difficult to achieve.

A variety of other techniques have been investigated to make a multiple-wavelength laser source. These approaches include an electrically pumped distributed-feedback laser array based on the hybrid bonding of III-V materials onto silicon. However, the yield and scaling of these laser arrays may make it difficult to obtain a low-cost laser source. In an alternative approach, a single broad-spectrum light emitter is used (such as: a superluminescent diode, a broadband laser, and a mode-locked comb laser) instead of the distributed-feedback laser array. Nonetheless, because of their size, cost and power consumption, the resulting laser sources also have not achieved a low-cost solution for use in a WDM silicon-photonic link. Furthermore, while a comb laser based on quantum dots has recently shown promise for transmitting wavelengths in the O band (1260-1360 nm), this laser source is not thought to be suitable for use in a WDM silicon-photonic link because of the limited availability of associated modulators and detectors.

Hence, what is needed is a multiple-wavelength laser source without the above-described problems.

### SUMMARY

One embodiment of the present disclosure provides a laser source that outputs an optical signal characterized by a wavelength associated with a lasing mode of the laser source. This laser source includes a first optical waveguide that includes a gain medium, and a second optical waveguide that includes a phase tuner which adjusts a phase value of the phase tuner to specify the wavelength of the laser source. Furthermore, the laser source includes a first ring resonator and a second ring resonator, which, respectively, are optically coupled to the first optical waveguide and the second optical waveguide at opposite ends of the laser source. Additionally, the laser source includes an optical amplifier, which is optically coupled to one of the first optical waveguide and the second optical waveguide, and which receives and amplifies the optical signal.

Note that the gain medium may include an electrically pumped gain medium. Furthermore, the phase value of the phase tuner may be thermally tunable.

In some embodiments, the first ring resonator includes a second phase tuner that matches a coupling wavelength of the first ring resonator with the wavelength of the optical signal, thereby optically coupling the optical signal between the first optical waveguide and the second optical waveguide. In addition, the second ring resonator may include a third phase tuner that matches a coupling wavelength of the second ring resonator with the wavelength of the optical signal, thereby optically coupling the optical signal between the first optical waveguide and the second optical waveguide. Note that the phase values of the second phase tuner and the third phase tuner may be thermally tunable.

Additionally, in some embodiments the optical signal is characterized by multiple wavelengths associated with multiple lasing modes of the laser source.

In some embodiments, the laser source is disposed on an integrated circuit. Moreover, the first optical waveguide, the second optical waveguide, the first ring resonator and the second ring resonator may be defined in a semiconductor layer (such as silicon) in the integrated circuit. Furthermore, the integrated circuit may include a substrate and a buried-oxide layer deposited on the substrate, where the semiconductor layer is disposed on the buried-oxide layer.

In some embodiments, a free-spectral range of the first ring resonator is different than a free-spectral range of the second ring resonator.

Another embodiment provides a method for outputting the optical signal using the laser source. During operation of the laser source, the phase value of the phase tuner in the first optical waveguide is adjusted, thereby selecting the wavelength of the output optical signal. Moreover, the coupling wavelength of the first ring resonator and the coupling wavelength of the second ring resonator are adjusted so that the coupling wavelength of the first ring resonator and the coupling wavelength of the second ring resonator match the wavelength of the optical signal. Then, the gain medium is pumped, and the optical signal is optically amplified using the optical amplifier.

Another embodiment provides a laser source that outputs an optical signal characterized by multiple wavelengths associated with multiple lasing modes of the laser source. This laser source includes multiple optical resonance loops that output the multiple wavelengths. Moreover, a given optical resonance loop includes: the first optical waveguide, the second optical waveguide and the phase tuner, the first ring resonator, and the second ring resonator. Furthermore, the laser source includes an optical multiplexer that selectively couples outputs from the multiple optical resonance loops to the optical amplifier.

Note that the optical multiplexer may include a set of ring resonators, where a given ring resonator is selectively optically coupled to the given optical resonance loop, thereby selectively optically coupling the wavelength output by the given optical resonance loop to the optical multiplexer. Furthermore, the coupling wavelength of the first ring resonator, the coupling wavelength of the second ring resonator, and the coupling wavelength of the given ring resonator in the optical multiplexer may match the wavelength output by the given optical resonance loop, but may be different from wavelengths output by other optical resonance loops in the multiple optical resonance loops.

Another embodiment provides a system that includes the multiple-wavelength laser source.

### BRIEF DESCRIPTION OF THE FIGURES

FIG. 1 is a block diagram of a laser source that outputs an optical signal characterized by at least a wavelength associated with a lasing mode of the laser source in accordance with an embodiment of the present disclosure.

FIG. 2 is a block diagram of a laser source that outputs an optical signal characterized by multiple wavelengths associated with multiple lasing modes of the laser source in accordance with an embodiment of the present disclosure.

FIG. 3 is a block diagram illustrating an integrated circuit in accordance with an embodiment of the present disclosure.

FIG. 4 is a block diagram illustrating a system that includes the laser source of FIG. 1 or 2 in accordance with an embodiment of the present disclosure.

FIG. 5 is a flow chart illustrating a method for outputting an optical signal using the laser source of FIG. 1 or 2 in accordance with an embodiment of the present disclosure.

Note that like reference numerals refer to corresponding parts throughout the drawings. Moreover, multiple instances of the same part are designated by a common prefix separated from an instance number by a dash.

### DETAILED DESCRIPTION

Embodiments of a laser source, a system that includes the multiple-wavelength laser source, and a technique for outputting an optical signal using the laser source are described. In the laser source, a first optical waveguide includes a gain medium, and a second optical waveguide includes a phase tuner which adjusts a phase value of the phase tuner to specify the wavelength of the laser source. Furthermore, the laser source includes a first ring resonator and a second ring resonator, which, respectively, are optically coupled to the first optical waveguide and the second optical waveguide at opposite ends of the laser source. In particular, coupling wavelengths of the first and second ring resonators may match at least a wavelength of the optical signal, thereby defining an optical resonance cavity in the laser source and selecting a laser mode of the laser source which is associated with the wavelength. Additionally, the laser source includes an optical amplifier that receives and amplifies the optical signal output from the optical resonance cavity.

By defining the optical resonance cavity using the first and second ring resonators, this optical technique may allow a low-cost, monolithic laser source to be implemented for use in a variety of applications, such as a WDM silicon-photonic link. Furthermore, the optical resonance cavity may be tunable, for example, by thermally tuning either or both of the ring resonators. Consequently, the laser source may help facilitate high-speed inter- and intra-chip silicon-photonic interconnects, as well as associated systems that can include this component (such as high-performance computing systems).

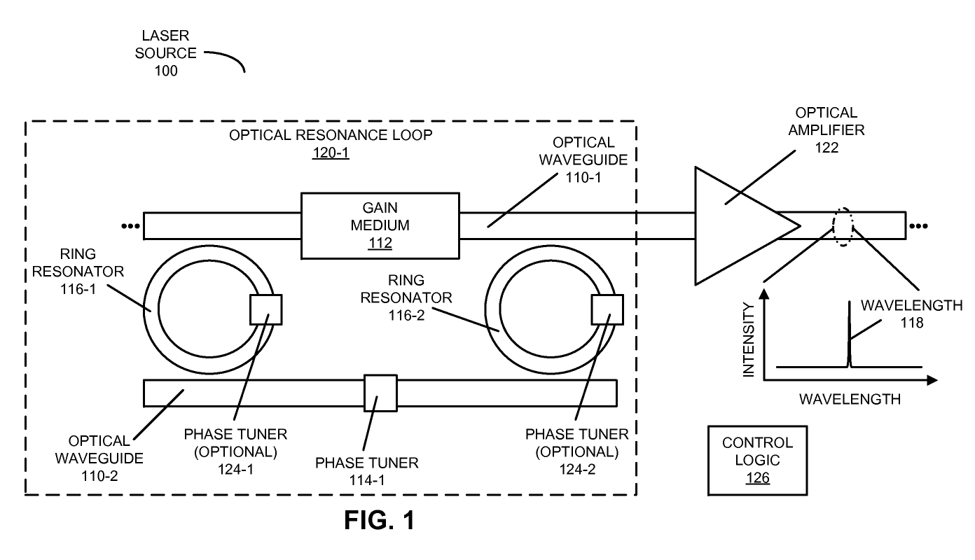

We now describe embodiments of the laser source. FIG. 1 presents a block diagram of a laser source 100 that outputs an optical signal characterized by at least a wavelength 118 associated with a lasing mode of laser source 100 (such as a carrier wavelength for use in an optical channel in an optical link) This laser source includes an optical waveguide 110-1 that includes a gain medium 112, such as an electrically pumped gain medium. For example, gain medium 112 may include indium-phosphide (and, more generally, hybrid bonded III-IV semiconductors) or germanium. In addition, laser source 100 may include an optical waveguide 110-2 that includes a phase tuner 114-1 which adjusts a phase value of the phase tuner to specify the wavelength of laser source 100. For example, the phase value of phase tuner 114-1 may be thermally tunable using a heater (not shown) in or proximate to phase tuner 114-1. Alternatively, a p-i-n tuner may be used. Note that optical waveguides 110 are sometimes referred to as ‘bus waveguides.’

Furthermore, laser source 100 includes ring resonators 116 (or ring-resonator reflectors), which, respectively, are optically coupled to optical waveguides 110 at opposite ends of laser source 100. These ring resonators define an optical resonance loop 120-1 (or the laser cavity) in laser source 100. This optical resonance loop may be used to support many lasing modes or wavelengths in gain medium 112. In addition, the coupling wavelengths of ring resonators 116 may selectively enhance at least the wavelength from a broad spectrum of lasing wavelengths that are modulated by the gain of active gain medium 112, i.e., at least the wavelength is selected from the lasing wavelengths that gain medium 112 supports. In this way, the optical signal having at least the high-gain wavelength is generated.

Additionally, laser source 100 includes an optical amplifier 122 (such as a silicon optical amplifier), which is optically coupled to one of optical waveguides 110, and which receives and amplifies the optical signal. In this way, optical resonance loop 120-1 provides at least the wavelength, while optical amplifier 122 provides the power.

Note that a given ring resonator in ring resonators 116 may be characterized by its: quality (Q) factor, bandwidth, coupling wavelength to optical waveguides 110, and/or free-spectral range (or, equivalently, its size, such as the radius of the given ring resonator). (Note that a small ring resonator has a large free-spectral range, and a large ring resonator has a small free-spectral range.) Furthermore, ring resonators 116 may be critically or optimally coupled to optical waveguides 110 so that at the resonance or coupling wavelength of the given ring resonator (as well as possibly at its integer multiples or harmonics) there is maximal transfer of energy from one component to the next in optical resonance loop 120-1 without or with reduced reflections, such as the energy transfer from optical waveguide 110-1 to ring resonator 116-1, etc. Note that the Q factor and the bandwidth may determine the width of the filtering by the given ring resonator, and thus the sharpness of at least the wavelength. In addition, the Q factor of the given ring resonator may be specified by or may be a function of the optical coupling between optical waveguides 110 and the given ring resonator, as well as a round-trip optical loss in the given ring resonator.

In some embodiments, ring resonators 116 have high quality (Q) factors, narrow bandwidths (or passbands) and/or free-spectral range(s) that are larger than a lasing bandwidth of gain medium 112 so that they can each pick out or select at least the wavelength (or a group of wavelengths having a line spacing that is less than the free-spectral ranges). For example, the given ring resonator may have a radius between 7-10 μm and a free-spectral range between 20-30 nm. Alternatively or additionally, ring resonators 116 may have slightly different coupling wavelengths so that only common harmonics or multiples of the coupling wavelengths are selected by optical resonance loop 120-1 (as opposed to all harmonics multiplied by the free-spectral range, in embodiments where the free-spectral range is less than the lasing bandwidth of gain medium 112), thereby providing an effect analogous to a Vernier. In this way, the given ring resonator (such as ring resonator 116-1) may optically couple or ‘reflect’ at least the wavelength from optical waveguide 110-1 to optical waveguide 110-2.

(However, in some embodiments ring resonators 116 may pick out or select multiple wavelengths or sets of wavelengths, which each may include a group of wavelengths, based on their free-spectral ranges and Q factors. For example, the given ring resonator may have a radius between 30-100 μm and a free-spectral range between 1-2 nm. Note that, if the multiple wavelengths or sets of wavelengths are within the lasing bandwidth of gain medium 112, the free-spectral range(s) and the coupling wavelengths of ring resonators 116 may determine a spacing between these wavelengths.)

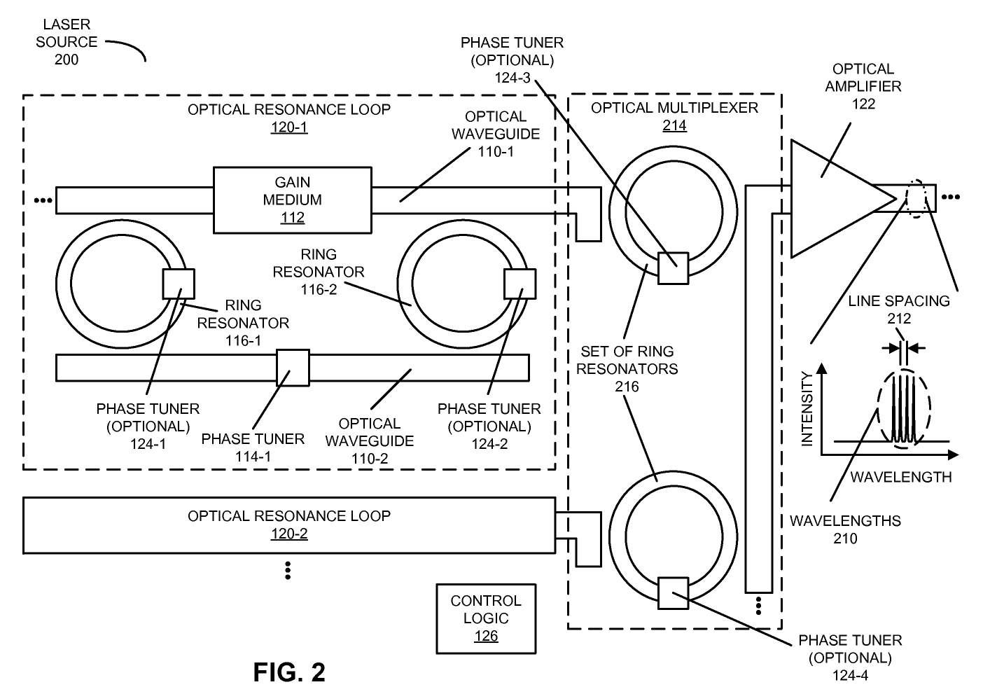

In an exemplary embodiment, ring resonators 116 (and/or set of ring resonators 216 in optical multiplexer 214 in FIG. 2) are tuned because manufacturing tolerances result in large variations in the coupling wavelengths across a wafer (or integrated circuit) and/or between wafers. In particular, ring resonator 116-1 may include an optional phase tuner 124-1 that matches a coupling wavelength of the ring resonator 116-1 with the wavelength of the optical signal, thereby optically coupling the optical signal between optical waveguides 110. In addition, ring resonator 116-2 may include an optional phase tuner 124-2 that matches a coupling wavelength of ring resonator 116-2 with the wavelength of the optical signal, thereby optically coupling the optical signal between the optical waveguides 110. In this way, at least the wavelength in the optical signal output by optical resonance loop 120-1 can be tuned, i.e., the lasing mode may be selectable (for example, using control logic 126).

Note that the phase values of optional phase tuners 124 may be thermally tunable because electrical tuning may spoil the Q factor of ring resonators 116 by adding additional loss into the ring-resonator waveguide(s). (Nonetheless, in some embodiments electronic tuning is used, for example, a p-i-n tuner.) However, thermal tuning may result in increased power consumption.

Furthermore, note that if identically sized ring resonators are fabricated on different wafers or far apart on a given wafer, then it may be necessary to tune the given ring resonator over the entire free-spectral range in order to select at least the wavelength. This may require between 5 and 100 mW of additional power even for small ring resonators (i.e., the additional power may be independent of the size of the ring resonator). This may reduce the efficiency of the laser and may also result in increased complexity because the resonance or coupling wavelengths of each of the ring resonators may need to be carefully monitored and matched (or adjusted).

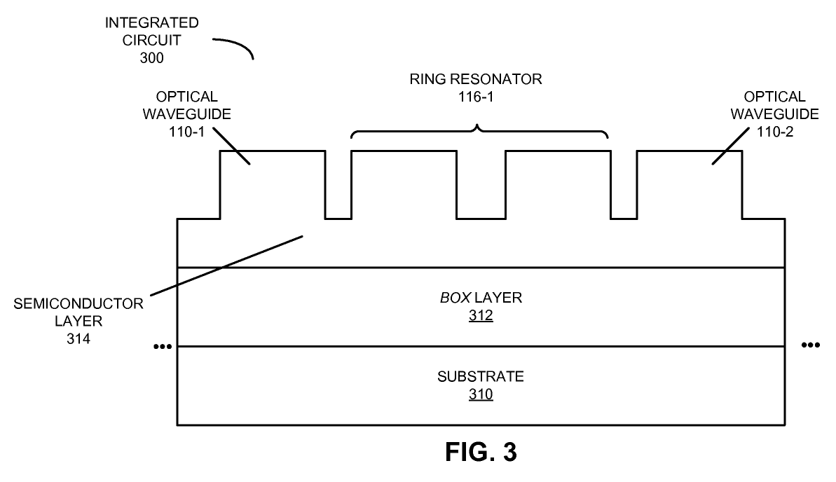

However, identically sized ring resonators that are placed close together on a wafer are much more likely, in a statistical sense, to have a close match in their resonance or coupling wavelengths. This may favor an integrated approach in which ring resonators having identical (or nearly identical) sizes are placed in close proximity, so that a first ring resonator or a pair of ring resonators that determines at least the wavelength of lasing is closely matched to other ring resonators, such as the set of ring resonators 216 in FIG. 2. (As described further below with reference to FIG. 2, this may allow optical multiplexing of multiple wavelengths into a single waveguide or optical link.) Thus, a monolithic or integrated laser source (such as that described below with reference to FIG. 3) may reduce the tuning energy, and may simplify the overall laser source because the temperatures (or, more generally, the phase values) of each of the ring resonators may not need to be independently monitored. Instead, the thermal properties of the laser source can be tailored to ensure that the coupling wavelengths of the ring resonators move in unison.

As noted previously, in some embodiments laser source 100 may output an optical signal characterized by multiple wavelengths associated with multiple lasing modes of laser source 100. However, this can result in: mode competition, large relative intensity noise and/or other impairments. Furthermore, it may be difficult to independently select the multiple wavelengths.

Additionally, degrees of freedom (i.e., one that is not constrained by the free-spectral range of the given ring resonator) and improved performance may be obtained by multiplexing multiple single wavelength sources to obtain a multiple-wavelength laser source. This is shown in FIG. 2, which presents a block diagram of a laser source 200. This laser source includes multiple cascaded optical resonance loops 120 that output the multiple wavelengths 210 having line spacing 212. Moreover, a given optical resonance loop (such as optical resonance loop 120-1) includes: optical waveguides 110, a phase tuner (such as phase tuner 114-1), and ring resonators 116. Furthermore, laser source 200 includes an optical multiplexer 214 that selectively couples to outputs from one or more of multiple optical resonance loops 120 (i.e., wavelength multiplexing) to optical amplifier 122. This optical multiplexer may include set of cascaded ring resonators 216, where a given ring resonator is selectively optically coupled to the given optical resonance loop (such as optical resonance loop 120-1), thereby selectively optically coupling the wavelength output by the given optical resonance loop to optical multiplexer 214.

Note that the coupling wavelength(s) of ring resonators in the given optical resonance loop in optical multiplexer 214 may match the wavelength output by the given optical resonance loop, but may be different from wavelengths output by other optical resonance loops in multiple optical resonance loops 120. Thus, the coupling wavelengths across a ‘row’ in FIG. 2 may be the same (or may be similar to each other so that the output of the given optical resonance loop includes the wavelength), but the coupling wavelengths in a ‘column’ (or across ‘rows’) in FIG. 2 may be different. Note that as long as the filtering associated with the ring resonators in a ‘row’ in laser source 200 is aligned with the WDM multiplexer/de-multiplexer in an optical link in an optical channel, drifting of the given optical resonance loop may not have a significant impact on performance.

Furthermore, ring resonators 116 in laser source 200 may have a wide free-spectral range and the ring resonators in different ‘rows’ of laser source 200 may be widely spaced so that all wavelengths can be covered. For example, relatively small ring sizes may be selected so that the corresponding free-spectral ranges are larger than the lasing bandwidth of gain medium 112. In this way, only one lasing mode may be supported by the given optical resonance loop.

In some embodiments, phase tuners 112 are thermally tuned. Alternatively or additionally, electronic tuning may be used, for example, p-i-n tuners. In addition, such thermal or electronic tuning may be used in ring resonators 116 and/or set of ring resonators 216. In this way, the cavity mode spacing can be fine tuned and/or the lasing wavelength of the given optical resonance loop can be selected. Note that, in embodiments where laser source 200 provides the output signal to an optical link, the tuning power for ring resonators 116 and/or phase tuners 114 may be amortized over many optical channels.

In an exemplary embodiment, multiple laser wavelengths from optical resonance loops or laser cavities that are tuned to different wavelengths are multiplexed into the same waveguide using cascaded ring resonators in the set of ring resonators 216 to establish a comb of lasers. For better overall power efficiency, the actively tuned optical resonance loops generate the desired wavelength channels only, not the power in the output from laser source 200. Instead, power is provided by optical amplifier 122 (such as a silicon optical amplifier), which boosts the power of all wavelengths in the output signals as needed (for example, based on the power requirements of a particular application such as a WDM optical link).

In this way, an ultra-compact, multiple-wavelength laser can be implemented without using optical feedback (such as that which can be provided using diffraction gratings or Fabry-Perot facets). This laser may provide: low-power wavelength tuning and, as described below with reference to FIG. 3, a monolithically integrated solution. Furthermore, there may be good registration of the laser wavelengths to optical multiplexer 214 by virtue of the proximate integration of optical resonance loops 120 and optical multiplexer 214.

In some embodiments, laser source 100 (FIG. 1) and/or 200 is disposed on an integrated circuit. This is shown in FIG. 3, which presents a block diagram illustrating an integrated circuit 300. In this integrated circuit, optical waveguides 110 and ring resonators 116 may be defined in a semiconductor layer 314. Furthermore, integrated circuit 300 may include a substrate 310 and a buried-oxide layer (BOX) 312 deposited on substrate 310, where semiconductor layer 314 is disposed on buried-oxide layer 312.

Note that substrate 310 may include silicon, buried-oxide layer 312 may include a dielectric or an oxide (such as silicon dioxide), and/or semiconductor layer 314 may include silicon (thus, optical waveguides 110 may include silicon waveguides). Therefore, substrate 310, buried-oxide layer 312 and semiconductor layer 314 may constitute a silicon-on-insulator (501) technology. In some embodiments, the silicon in semiconductor layer 314 is 0.5 μm thick, and the silicon-dioxide layer may have a thickness between 0.1 and 10 μm. Note that in order to facilitate integration of gain medium 112 (FIGS. 1 and 2) and semiconductor layer 314, buffer layers may be used between gain medium 112 (FIGS. 1 and 2) and semiconductor layer 314, as is known to one of skill in the art.

Note that in the embodiments, such as FIG. 3, the light is confined in semiconductor layer 314 and may be surrounded on all sides (including below) by an oxide. However, in other embodiments a waveguide ring or a waveguide modulator may be fabricated using a different confinement, such as a polymer ring deposited on an oxide, or poly-silicon surrounded by an oxide (in which case buried-oxide layer 312 may not be needed).

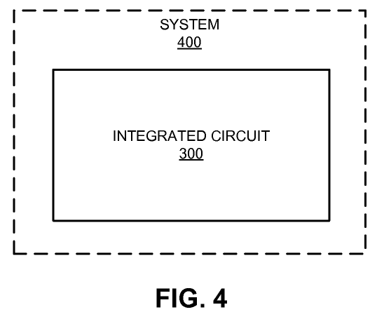

One or more of the preceding embodiments of the laser source may be included in a system and/or an electronic device. This is illustrated in FIG. 4, which presents a block diagram illustrating a system 400 that includes integrated circuit 300.

The laser source may be used in a variety of applications, including: VLSI circuits, communication systems (such as WDM), storage area networks, data centers, networks (such as local area networks), and/or computer systems (such as multiple-core processor computer systems). Note that system 400 may include, but is not limited to: a server, a laptop computer, a communication device or system, a personal computer, a work station, a mainframe computer, a blade, an enterprise computer, a data center, a portable-computing device, a supercomputer, a network-attached-storage (NAS) system, a storage-area-network (SAN) system, and/or another electronic computing device. Moreover, note that a given computer system may be at one location or may be distributed over multiple, geographically dispersed locations.

For example, the output from laser source 100 (FIG. 2) and/or 200 (FIG. 2), with appropriate tuning of the wavelengths, may be used in corresponding optical channels in an optical link. In this embodiment, one or more wavelengths output by laser source 200 (FIG. 2) may be modulated by one or more modulators to encode data for a given optical channel onto wavelengths in the one or more wavelengths. This modulation may be independent of that performed by other modulators on other wavelengths in the output signal. After a given wavelength has been modulated, the modulated optical signals may be combined by a combiner and output onto a common optical link. (In general, the optical signals can be modulated before or after combining.)

Note that either narrow-band or broad-band modulators may be used. In embodiments where narrow-band modulation is used, such as using ring-resonator modulators, which are usually associated with a very small ring-resonance shift (on the order of a few tens of picometers), the wavelengths for each of the optical channels may need to have a very narrow line width (such as less than a few picometers). Therefore, these embodiments may use highly accurate tuning of these components. Alternatively, if broadband modulators are used to encode data on the outputs from a multiple-wavelength laser source (such as a Mach-Zehnder-interferometer modulator, an electro-absorption modulator, and/or a modulator that has a bandwidth greater than 10 nm), the laser-source line widths may be relaxed to sub-nanometers if the transmission is high-speed (e.g., greater than 10 Gbps) and is over short distances.

Laser source 100 (FIG. 1), laser source 200 (FIG. 2), integrated circuit 300 (FIG. 3) and/or system 400 may include fewer components or additional components. For example, semiconductor layer 314 in FIG. 3 may include poly-silicon or amorphous silicon. Furthermore, a wide variety of fabrication techniques may be used to fabricate the laser source in the preceding embodiments, as is known to one of skill in the art. In addition, a wide variety of optical components may be used in or in conjunction with the laser source (such as alternative optical filters that replace ring resonators 116 in FIGS. 1 and 2).

While gain medium 112 is included in optical waveguide 110-1 in FIGS. 1 and 2, in other embodiments a wide variety of gain elements and lasers may be used, including: a semiconductor laser, a Fabry-Perot laser, a laser that receives and outputs light from the same facet, etc. Furthermore, in some embodiments laser source 100 (FIG. 1) or 200 (FIG. 2) may be replaced by a non-lasing optical source, such as a semiconductor optical amplifier.

Although these embodiments are illustrated as having a number of discrete items, the embodiments of the laser source, the integrated circuit and the system are intended to be functional descriptions of the various features that may be present rather than structural schematics of the embodiments described herein. Consequently, in these embodiments two or more components may be combined into a single component, and/or a position of one or more components may be changed.

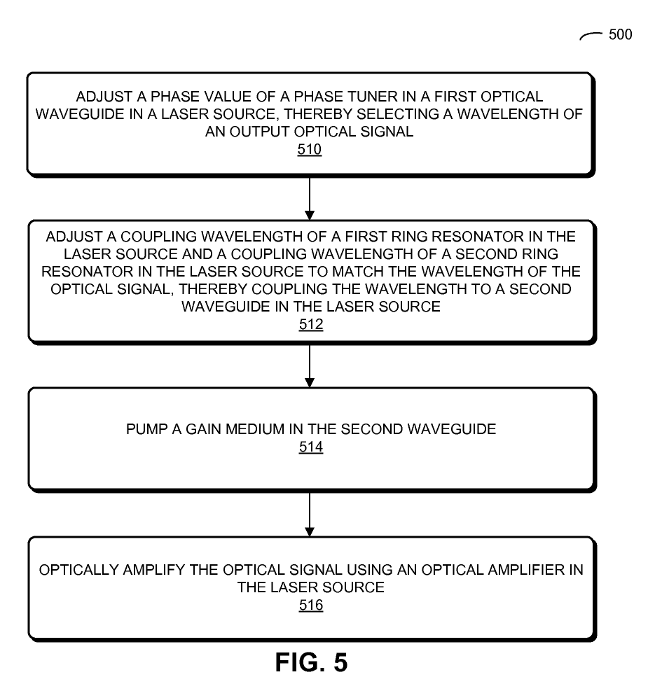

We now describe embodiments of the method. FIG. 5 presents a flow chart illustrating a method 500 for outputting an optical signal using a laser source, such as laser source 100 (FIG. 1) and/or 200 (FIG. 2). During operation of the laser source, the phase value of the phase tuner in the first optical waveguide is adjusted (operation 510), thereby selecting the wavelength of the output optical signal. Moreover, the coupling wavelength of the first ring resonator and the coupling wavelength of the second ring resonator are adjusted so that the coupling wavelength of the first ring resonator and the coupling wavelength of the second ring resonator match the wavelength of the optical signal (operation 512), thereby coupling the wavelength to the second waveguide. Then, the gain medium in the second waveguide is pumped (operation 514), and the optical signal is optically amplified using the optical amplifier (operation 516).

In some embodiments of method 500, there may be additional or fewer operations. Moreover, the order of the operations may be changed, and/or two or more operations may be combined into a single operation.

While the preceding embodiments illustrate the use of the laser source in conjunction with an optical link, the laser source may be used in applications other than communications, such as: manufacturing (cutting or welding), a lithographic process, data storage (such as an optical-storage device or system), medicine (such as a diagnostic technique or surgery), a barcode scanner, entertainment (a laser light show), and/or metrology (such as precision measurements of distance).

The foregoing description is intended to enable any person skilled in the art to make and use the disclosure, and is provided in the context of a particular application and its requirements. Moreover, the foregoing descriptions of embodiments of the present disclosure have been presented for purposes of illustration and description only. They are not intended to be exhaustive or to limit the present disclosure to the forms disclosed. Accordingly, many modifications and variations will be apparent to practitioners skilled in the art, and the general principles defined herein may be applied to other embodiments and applications without departing from the spirit and scope of the present disclosure. Additionally, the discussion of the preceding embodiments is not intended to limit the present disclosure. Thus, the present disclosure is not intended to be limited to the embodiments shown, but is to be accorded the widest scope consistent with the principles and features disclosed herein.

What is claimed is:

1. A laser source configured to output an optical signal characterized by at least a wavelength associated with a lasing mode of the laser source, comprising:
a first optical waveguide including a gain medium;
a second optical waveguide including a phase tuner, wherein the phase tuner is configured to adjust a phase value of the phase tuner to specify the wavelength of the laser source;
a first ring resonator optically coupled to the first optical waveguide and the second optical waveguide at a first end of the laser source;
a second ring resonator optically coupled to the first optical waveguide and the second optical waveguide at a second end of the laser source; and
an optical amplifier optically coupled to one of the first optical waveguide and the second optical waveguide, wherein the optical amplifier is configured to receive and amplify the optical signal.

2. The laser source of claim 1, wherein the gain medium includes an electrically pumped gain medium.

3. The laser source of claim 1, wherein the phase value of the phase tuner is thermally tunable.

4. The laser source of claim 1, wherein the first ring resonator includes a second phase tuner to match a coupling wavelength of the first ring resonator with the wavelength of the optical signal, thereby optically coupling the optical signal between the first optical waveguide and the second optical waveguide; and
wherein the second ring resonator includes a third phase tuner to match a coupling wavelength of the second ring resonator with the wavelength of the optical signal, thereby optically coupling the optical signal between the first optical waveguide and the second optical waveguide.

5. The laser source of claim 4, wherein the phase values of the second phase tuner and the third phase tuner are thermally tunable.

6. The laser source of claim 1, wherein the optical signal is characterized by multiple wavelengths associated with multiple lasing modes of the laser source.

7. The laser source of claim 1, wherein the laser source is disposed on an integrated circuit.

8. The laser source of claim 7, wherein the first optical waveguide, the second optical waveguide, the first ring resonator and the second ring resonator are defined in a semiconductor layer in the integrated circuit.

9. The laser source of claim 8, wherein the semiconductor layer includes silicon.

10. The laser source of claim 8, further comprising:
a substrate; and
a buried-oxide layer deposited on the substrate, wherein the semiconductor layer is disposed on the buried-oxide layer.

11. The laser source of claim 1, wherein a free-spectral range of the first ring resonator is different than a free-spectral range of the second ring resonator.

12. A method for outputting an optical signal using a laser source, wherein the optical signal is characterized by at least a wavelength associated with a lasing mode of the laser source, the method comprising:
adjusting a phase value of a phase tuner in a first optical waveguide in the laser source, thereby selecting the wavelength of the output optical signal;
adjusting a coupling wavelength of a first ring resonator in the laser source and adjusting a coupling wavelength of a second ring resonator in the laser source so that the coupling wavelength of the first ring resonator and the coupling wavelength of the second ring resonator match the wavelength of the optical signal, wherein the first ring resonator and the second ring resonator optically couple the first optical waveguide to a second optical waveguide in the laser source;
pumping a gain medium in the second optical waveguide; and
optically amplifying the optical signal using an optical amplifier in the laser source, wherein the optical amplifier is optically coupled to one of the first optical waveguide and the second optical waveguide.

13. A laser source, wherein the laser source is configured to output an optical signal characterized by multiple wavelengths associated with multiple lasing modes of the laser source, comprising:
multiple optical resonance loops configured to output the multiple wavelengths, wherein a given optical resonance loop includes:
a first optical waveguide including a gain medium;
a second optical waveguide including a phase tuner, wherein the phase tuner is configured to adjust a phase value of the phase tuner to specify a wavelength output by the given optical resonance loop;
a first ring resonator optically coupled to the first optical waveguide and the second optical waveguide at a first end of the given optical resonance loop; and
a second ring resonator optically coupled to the first optical waveguide and the second optical waveguide at a second end of the given optical resonance loop;
an optical multiplexer selectively coupled to outputs from the multiple optical resonance loops, wherein a given output from the given optical resonance loop is optically coupled to one of the first optical waveguide and the second optical waveguide; and
an optical amplifier optically coupled to the optical multiplexer, wherein the optical amplifier is configured to receive and amplify the optical signal.

14. The laser source of claim 13, wherein the optical multiplexer includes a set of ring resonators, wherein a given ring resonator is selectively optically coupled to the given optical resonance loop, thereby selectively optically coupling the wavelength output by the given optical resonance loop to the optical multiplexer.

15. The laser source of claim 14, wherein the coupling wavelength of the first ring resonator, the coupling wavelength of the second ring resonator, and the coupling wavelength of the given ring resonator in the optical multiplexer match the wavelength output by the given optical resonance loop, but are different from wavelengths output by other optical resonance loops in the multiple optical resonance loops.

16. The laser source of claim 13, wherein the gain medium includes an electrically pumped gain medium.

17. The laser source of claim 13, wherein the phase value of the phase tuner is thermally tunable.

18. The laser source of claim 13, wherein the first ring resonator includes a second phase tuner to match a coupling wavelength of the first ring resonator with the wavelength of the optical signal, thereby optically coupling the optical signal between the first optical waveguide and the second optical waveguide; and
wherein the second ring resonator includes a third phase tuner to match a coupling wavelength of the second ring resonator with the wavelength output by the given optical resonance loop, thereby optically coupling the optical signal between the first optical waveguide and the second optical waveguide.

19. The laser source of claim 18, wherein the phase values of the second phase tuner and the third phase tuner are thermally tunable.

20. The laser source of claim 13, wherein the laser source is disposed on an integrated circuit; and
wherein the first optical waveguide, the second optical waveguide, the first ring resonator and the second ring resonator are defined in a semiconductor layer in the integrated circuit.
